(19) United States
(12) Patent Application Publication
(10) Pub. No.: US 2016/0035652 A1
(43) Pub. Date: Feb. 4, 2016

(54) Integrated Circuit Device With Wire Bond Connections

(71) Applicant: Texas Instruments Incorporated, Dallas, TX (US)

(72) Inventors: Genki Yano, Beppu City (JP); Ayumu Kuroda, Beppu City (JP)

(21) Appl. No.: 14/814,342

(22) Filed: Jul. 30, 2015

Related U.S. Application Data
(60) Provisional application No. 62/032,212, filed on Aug. 1, 2014.

(51) Int. Cl. H01L 23/495; H01L 23/31; H01L 23/00

(52) U.S. Cl. CPC H01L 23/49513; H01L 24/48; H01L 24/32; H01L 24/73; H01L 24/85; H01L 24/83; H01L 24/92; H01L 23/3107; H01L 24/11; H01L 2224/4845; H01L 2224/13144; H01L 2224/13147; H01L 2224/1134; H01L 2224/32245; H01L 2224/48106; H01L 2224/48247; H01L 2224/73265; H01L 2224/73257; H01L 2224/92127; H01L 2224/92247; H01L 2224/85205

(57) ABSTRACT

An integrated circuit assembly includes a die with a bond pad; a stud bump formed on the bond pad; and a ball bond formed on the stud bump.

### CROSS REFERENCE OF RELATED APPLICATIONS

This application claims the priority of U.S. Provisional Patent Application Ser. No. 62/032212, filed Aug. 1, 2014, which is hereby incorporated by reference for all that it discloses.

### BACKGROUND

In a typical prior art integrated circuit package, an integrated circuit die is mounted on the die attach pad of a leadframe. Contact pads on the die are connected to leads of the leadframe by wire bonding. This assembly is encapsulated in a protective material such as mold compound that at least partially exposes the leadframe.

In conventional wire bonding a tool known as a capillary forms a ball bond on the bond pad of a die. A small diameter bond wire of the same metal as the ball bond has one end that is integral with the ball bond and a distal end. The distal end is attached to a corresponding lead of the leadframe with a stitch bond.

During ball bonding, the molten ball of metal is initially formed at the end of the capillary. The molten ball is then moved by the capillary to place it in contact with the metal die bond pad. Stitching is performed by pressing the capillary against the bond wire and a top surface of the corresponding lead. Heat and ultrasonic vibration are usually applied by the capillary at the same time to form the ball for a ball bond and to complete a stitch bond. The pressure, heat and vibration cause the ball or the distal end of the wire to partially melt and bond with the adjacent metal surface to which it is attached.

Ball bonding and ball bonding machines are described in detail in U.S. patent application Ser. No. 13/345,460 of Wade Chang, et al., filed Jan. 6, 2012, Pub. No. 2013/0175677, which is hereby incorporated by reference for all that it contains.

### BRIEF DESCRIPTION OF THE DRAWINGS

FIG. 1 is a side elevation view of an integrated circuit assembly positioned in a wire bonding machine, which illustrates a problem in the prior art appreciated by the inventors.

FIG. 2 is a side elevation view of an example embodiment of a leadframe and die with a stud bump formed on the die.

FIG. 3 is a side elevation view of the assembly of FIG. 2 with a ball bond formed on the stud bump.

FIG. 4 is a cross sectional view of an example embodiment of an integrated circuit package.

FIG. 5 is a flow chart of an example embodiment of a method of making an integrated circuit assembly.

### DETAILED DESCRIPTION

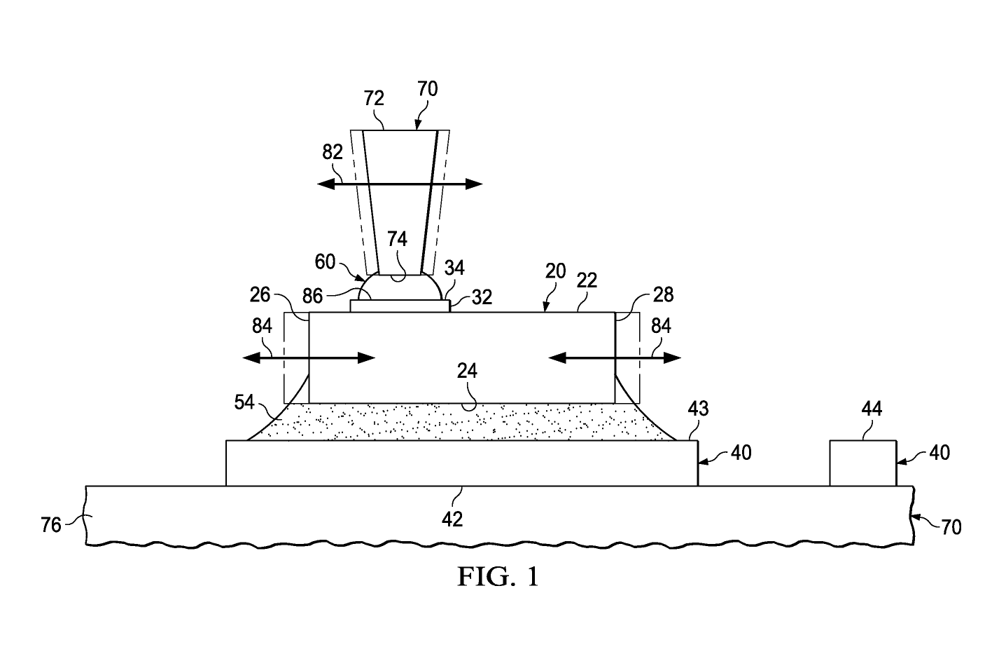

FIG. 1 is a side elevation view of an integrated assembly positioned in a wire bonding machine 70, that illustrates a problem in the prior art first appreciated by the inventors. The integrated circuit an integrated circuit die 20 having a top portion 22, a bottom portion 24 and lateral side portions 26, etc. A bond pad 32 is located on the top portion 22 of the die 20. The die 20 is mounted on a die attach pad (DAT) 42 of a leadframe 40 by a layer of low modulus die attachment material 50. As used herein “low modulus die attachment material” means material having a modulus of elasticity of less than about 100 MPa. The leadframe 40 has a plurality of leads 44 (only one shown).

A wire bonding tool 70, as shown in FIG. 1, includes a capillary 72 having a tip portion 74 from which a bond wire (not shown in FIG. 1) may be paid out during wire bonding. The wire bonding tool also includes a table 76 that supports the leadframe 40 during wire bonding.

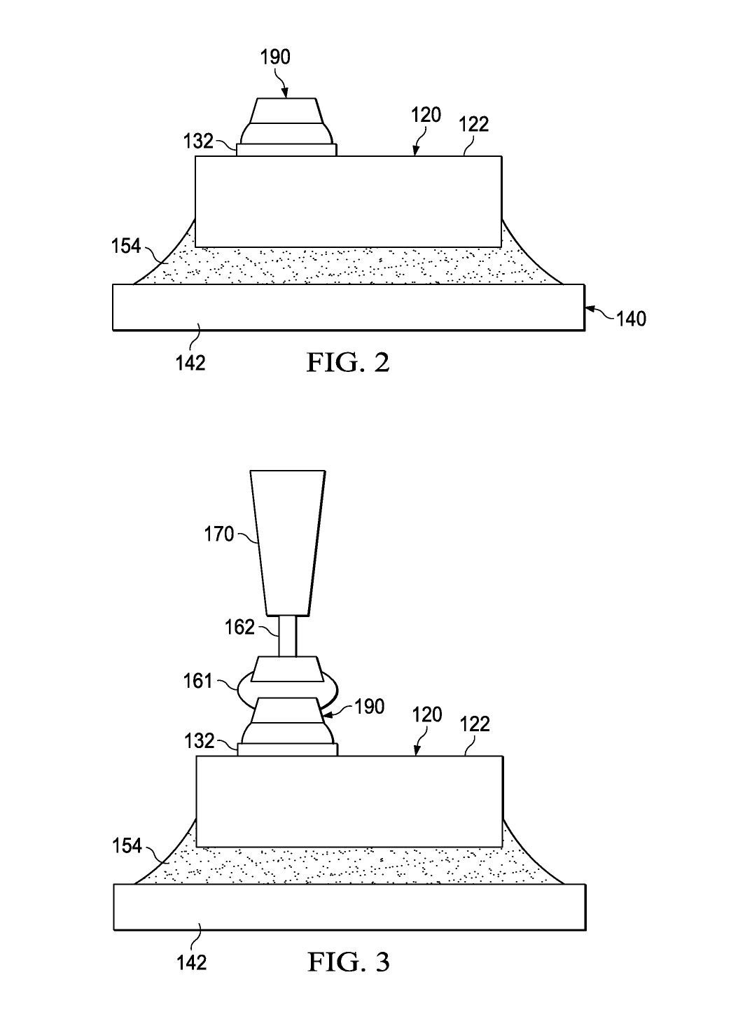

The die 20 is attached to the leadframe 40 by a layer of a low modulus attachment material, for example, a material having a modulus of elasticity less than or equal to about 100 MPa. Such low modulus materials are sometimes specified in certain applications, such as sensor products. However, such low modulus materials can create a problem with a ball bond 60 that is formed on the die bond pad 32 as a part of wire bonding operations. This problem is exacerbated with extremely small dies, e.g., dies having a top face 22 measuring less than about 1.0 mm×1.0 mm. The problem arises from the ultrasonic vibration emitted by the wire bonding tool 70 for heating the bond wire to form the ball bond 60. As first appreciated by the inventors, ultrasonic vibration of the die bonding tool 70 causes lateral vibration, indicated at 82, in the capillary 72. When a low modulus material is used to attach the die 20 to the DAT 42 this vibration is transmitted through the ball bond to the die, which is laterally displaced by the ultrasonic vibration, as indicated at 84. Such die displacement produces poor bonding between the die bond pad 32 and the ball bond 60. The inventors have discovered that the quality of the bond between a die bond pad and ball bond may be improved by the structure described below with reference to FIGS. 2-4.

In FIGS. 2-4, structures that are generally the same as the structures described in FIG. 1 are given the same reference numerals as in FIG. 1, increased by 100.

FIG. 2 is a side elevation view of an example embodiment of a leadframe and die assembly. This assembly includes the same leadframe 140, die 120 and low modulus die attachment material 154 as described in reference to FIG. 1. However, one difference is that in the assembly of FIG. 2, a gold or other metal “stud bump” 190 (sometimes referred to as a “prior stud bump” or “first bump”) is formed on the die bond pad 132. In the assembly of FIG. 2, the stud bump may be formed using a capillary similar to the way that a ball bond if formed. It may be done before or after the die 20 is mounted on the leadframe 140. In one embodiment the stud bump is formed on the die before the die is singulated from a die wafer.

Referring now to FIG. 3, after the stud bump 190 is formed on the bond pad 132, then a ball bond 161 is formed on top of the stud bump 190. Applicants have discovered that for some reason, the combined stud bump 190 and ball bond 161 do not transmit ultrasonic vibration in a way that damages the bond between the ball bond 161 and the bond pad 132, at least not as much as in the prior art structure that does not include the stud bump 190 shown in FIG. 3. It is the inventors' theory that this improved result occurs, because of the gold to gold bonding that occurs between the stud bump 190 and a ball bond 161. Gold to gold connectability is better than the connectability between a typically aluminum bond pad 32 and a gold ball bond 60, as shown in FIG. 1.

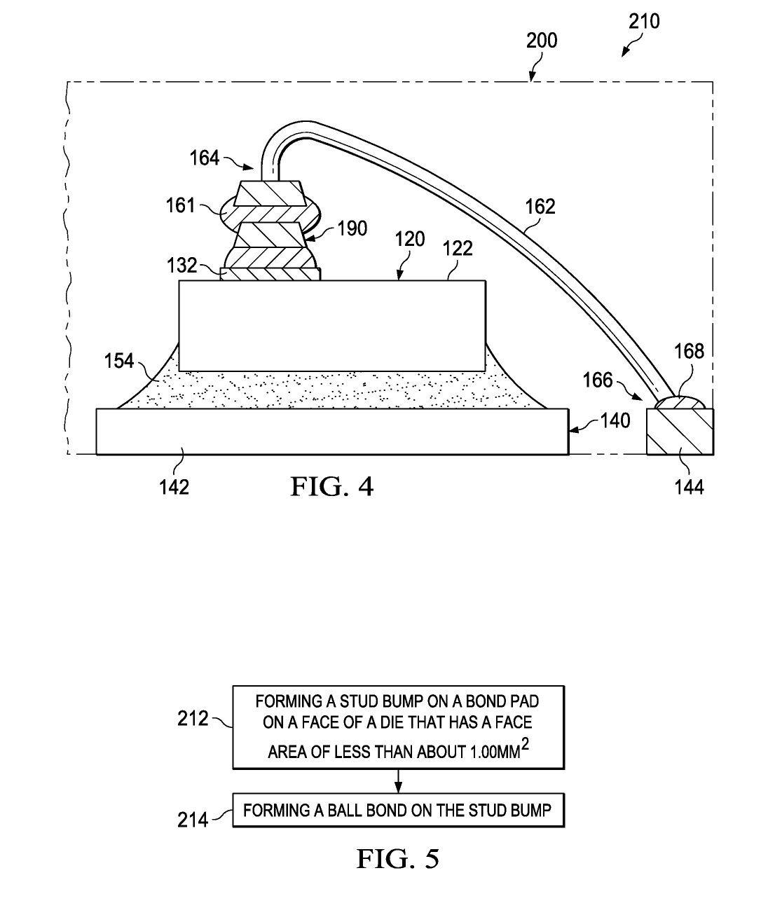

FIG. 4 is a cross-sectional view of an integrated circuit package 210 having a leadframe 142, die 120, die attach material 154, stud bump and ball bond 161, as described above in reference to FIG. 3. A bond wire 162 has a proximal end 164 integrally connected to the ball bond 161. The bond wire 162 has a distal end 168 connected to a lead 144 of the leadframe, as by a stich bond 166. An encapsulation layer 200, which may be mold compound, provides a protective coating that cover all of the described components except for portions of the leadframe.

The inventors believe that a structure such as described in FIG. 4, when used with a die having a top face of 1.0 mm X 1.0 mm, will allow the use of a die attach material having a modulus of elasticity of less than or equal to about 100 MPa, without producing a defective bond between the bond pad 132 and the stud bump 190 or between the stud bump 190 and the ball bond 161. It may even allow use of a die attach material having a modulus of elasticity as low as about 10 MPa, without producing defective bonds. Various materials and material combinations may be used in the integrated circuit package 210 of FIG. 4. 5. For example, the stud bump may be made from gold or copper or some other conductive metal, as may the ball bond. The stud bump and ball bond may be made from the same material or may be made from different materials.

FIG. 5 is a flow diagram of one embodiment of a method of forming an integrated circuit assembly. The method includes, as shown at block 212, forming a stud bump on a bond pad on a face of a die. The method also includes, as shown at block 214, forming a ball bond on the stud bump.

Other method embodiments may include the steps illustrated in Fig, 5 and other additional steps or variations of those steps. For example, the step of forming a stud bump may include forming a stud bump on a bond pad on a face of a die that has a face area of less than about 0.50 mm².

Another example includes the additional step of attaching the die to a leadframe with a material having a modulus of elasticity of less than about 100 MPa.

Another example includes the additional step of attaching the die to a leadframe with a material having a modulus of elasticity of less than about 90 MPa.

In another example, the step of forming a ball bond comprises forming a ball bond using ultrasonic energy.

In another example, the step of forming a stud bump on a bond pad on a face of a die that has a face area of less than about 1.00 mm² includes forming the stud bump with a capillary.

In another example, forming a stud bump on a bond pad on a face of a die that has a face area of less than about 1.00 mm² includes forming the stud bump when the die is still an integral portion of a semiconductor wafer.

In another example, forming a stud bump includes forming a gold stud bump and forming a ball bond on the stud bump includes forming a gold ball bond on the stud bump.

While various embodiments of the invention have been specifically described herein, it will be obvious to those having skill in the art that the invention may be otherwise variously embodied. The appended claims are to be construed to cover all such alternative embodiments except to the extent limited by the prior art.

What is claimed is:

1. An integrated circuit assembly comprising:
a die with a bond pad;
a stud bump formed on said bond pad; and
a ball bond formed on said stud bump.

2. The integrated circuit of claim 1 further comprising:
a leadframe; and
a low modulus of elasticity die mounting material attaching said die to said leadframe.

3. The integrated circuit of claim 2, wherein said low modulus of elasticity die mounting material has a modulus of elasticity of less than about 100 MPa.

4. The integrated circuit of claim 1 further comprising a bond wire integrally formed with said ball bond.

5. The integrated circuit of claim 1 wherein said stud bump is made from gold.

6. The integrated circuit of claim 1 wherein said stud bump is made from copper.

7. The integrated circuit of claim 1 wherein said ball bond is made from gold.

8. The integrated circuit of claim 1 wherein said ball bond is made from copper.

9. The integrated circuit of claim 1 wherein said stud bump and said ball bond are made from the same material.

10. The integrated circuit of claim 1 wherein said stud bump and said ball bond are made from different material.

11. A method of forming an integrated circuit assembly comprising:
forming a stud bump on a bond pad on a face of a die that has a face area of less than about 1.00 mm²,
forming a ball bond on the stud bump.

12. The method of claim 11, wherein said forming a stud bump comprises forming a stud bump on a bond pad on a face of a die that has a face area of less than about 0.50 mm².

13. The method of claim 11 further comprising attaching the die to a leadframe with a material having a modulus of elasticity of less than about 100 MPa.

14. The method of claim 12 further comprising attaching the die to a leadframe with a material having a modulus of elasticity of less than about 90 MPa.

15. The method of claim 11 wherein said forming a ball bond comprises forming a ball bond using ultrasonic energy.

16. The method of claim 11 wherein said forming a stud bump on a bond pad on a face of a die that has a face area of less than about 1.00 mm² comprises forming the stud bump with a capillary.

17. The method of claim 11 wherein said forming a stud bump on a bond pad on a face of a die that has a face area of less than about 1.00 mm² comprises forming the stud bump when the die is still an integral portion of a semiconductor wafer.

18. The method of claim 11 wherein forming a stud bump comprises forming a gold stud bump and wherein forming a ball bond on the stud bump comprises forming a gold ball bond on the stud bump.

19. An integrated circuit package comprising:
a die with a bond pad;
a stud bump formed on said bond pad;
a ball bond formed on said stud bump;
a leadframe to which said die is attached;
a material having a modulus of elasticity of less than about 50Mpa attaching said die to said leadframe; and
an encapsulant encapsulating said die, said stud bump; said ball bond and at least of portion of said leadframe.

20. The integrated circuit package of claim 19 further comprising a bond wire having one end integrally connected to said ball bond and another end that is stitch bonded to a lead portion of said leadframe.
